(19) United States
(12) Patent Application Publication
(10) Pub. No.: US 2026/0196875 A1
(43) Pub. Date: Jul. 9, 2026

(54) Mobile Charging device for a Mobile Electrostatic Carrier (MESC)

(71) Applicant: Eryn Smith, Danville, CA (US)

(72) Inventor: Eryn Smith, Danville, CA (US)

(21) Appl. No.: 19/013,896

(22) Filed: Jan. 8, 2025

(51) Int. Cl. H02J 50/10; H01L 21/683; H02J 7/00; H02J 50/00

(52) U.S. Cl. CPC H02J 50/10; H02J 50/005; H10P 72/722; H02J 7/70

(57) ABSTRACT

A mobile charging device is an apparatus that allows a mobile electrostatic carrier (MESC) to be charged anywhere. The apparatus includes a device housing, a microprocessor, a memory module, a portable power source, a voltage booster circuit, a wireless charging coil, and at least one trigger sensor. The device housing encloses and/or serves as a base for the other components. The microprocessor and the memory module store, transfer, and process digital information and digital instructions. The portable power source provides the electrical power to charge an MESC. The voltage booster circuit increases the voltage of this electrical power before reaching the wireless charging coil. The wireless charging coil inductively delivers the electrical power to an MESC. When an MESC is proximal to the wireless charging coil, the trigger sensor activates the voltage booster circuit and the portable power source.

### FIELD OF THE INVENTION

The present invention generally relates to an autonomous charging module used in conjunction with a foreign material (FM) abatement mobile electrostatic carrier (MESC). The present invention is a system and method that enables particle abatement for semiconductive-wafer processing tools. More specifically, the present invention is used to charge an MESC for the purpose of reducing FM's inside wafer processing systems. The present invention has been configured to be autonomous and can be implemented at any part of the wafer-processing workflow, wherein a tool in the wafer-processing workflow receives a PA-MESC (particle abatement mobile electrostatic carrier) [i.e., FOUP (front opening utility pod), load-port position, EFIM, process module, etc.].

### BACKGROUND OF THE INVENTION

With the advent of new technology, people are more reliant on electronic devices/systems in their daily routine. This causes an increase in manufacturing and production of electronic devices and systems. Manufacturing of smaller-and-smaller-end-user products has driven the semiconductor manufactures to continually decrease the size and power consumption of semiconductors.

The continued decrease in device size has caused a variety of challenges to the manufacturer, and the wafers are typically processed in controlled environments with very low FM contamination (i.e., cleanrooms with high efficiency particle arresting HEPA filtration and/or ultra-low particulate air (ULPA) filtration help capture airborne FM's). One concern is the accumulation of FM's on the processing tools, which causes a myriad of issues discussed further and is well known in the art. Currently, there are not that many cost-effective and highly-yielding technologies to remove FM from the tools used in the wafer-processing workflow without a full teardown and clean. This poses a significant challenge to the efficient workflow of the manufacturing processes because a full tear down is costly and causes those tools to be out of production for extended periods of time. Work has been done with tacky wafers and tapes to remove FM's, but these technologies are not suitable in highly-integrated semiconductor manufacturing [i.e., <14-nanometer (nm) technology]. The tacky/tapes cause a technological hurdle because the wafers can be hard to remove and because there can be residues that are not easy to remove/clean.

Therefore, an objective of the present invention is to provide a method and apparatus that stores, charges, and logs data related to a MESC as described in the U.S. Pat. No. 11,772,136. The method is to run a charged MESC face down in a process tool so that a charged MESC can easily be moved to a lithography, etch, deposition, system or another system known in the art. The charged MESC can then use electrostatic forces to attract FM's from a process tool (e.g., a chuck/platen). Upon removal of the particles from a process tool to the charged MESC, then the MESC can easily be cleaned in standard wafer cleans, which is well known in the art.

### BRIEF DESCRIPTION OF THE DRAWINGS

FIG. 1 is a schematic diagram illustrating the electronic connections of the present invention.

FIG. 2 is a schematic diagram illustrating the electrical connections of the present invention.

FIG. 3 is a schematic diagram illustrating the present invention mounted within an enclosure that is used to store multiple mobile electrostatic carriers.

FIG. 4 is a schematic diagram illustrating a software interface to adjust any parameters and/or programable features managed by the microprocessor of the present invention.

### DETAILED DESCRIPTION OF THE INVENTION

All illustrations of the drawings are for the purpose of describing selected versions of the present invention and are not intended to limit the scope of the present invention.

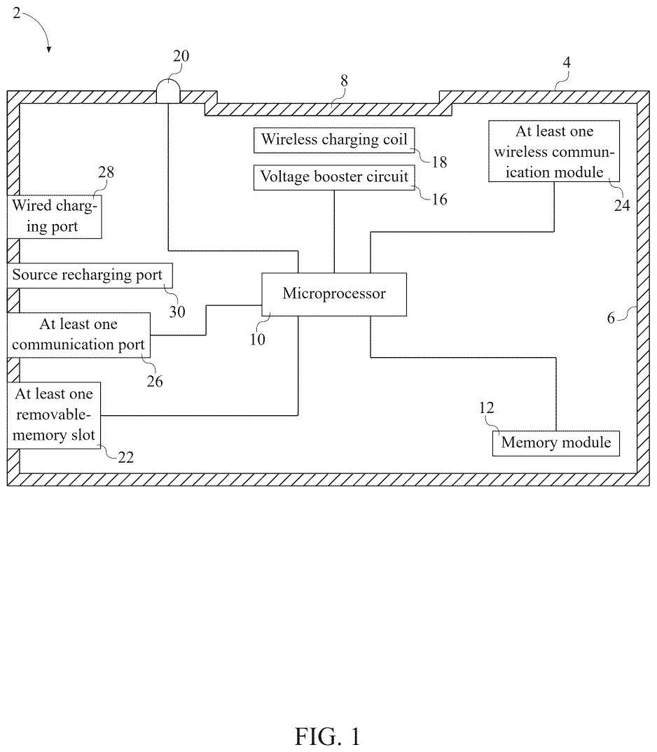

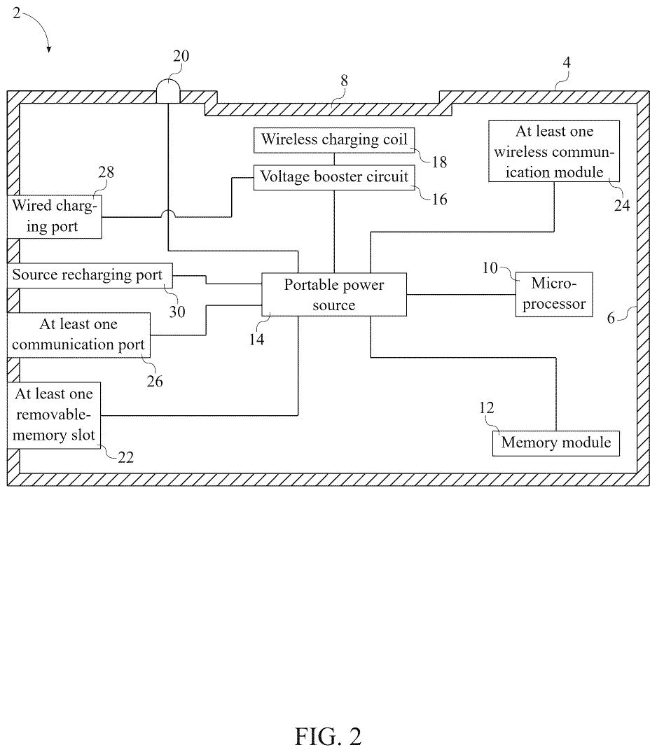

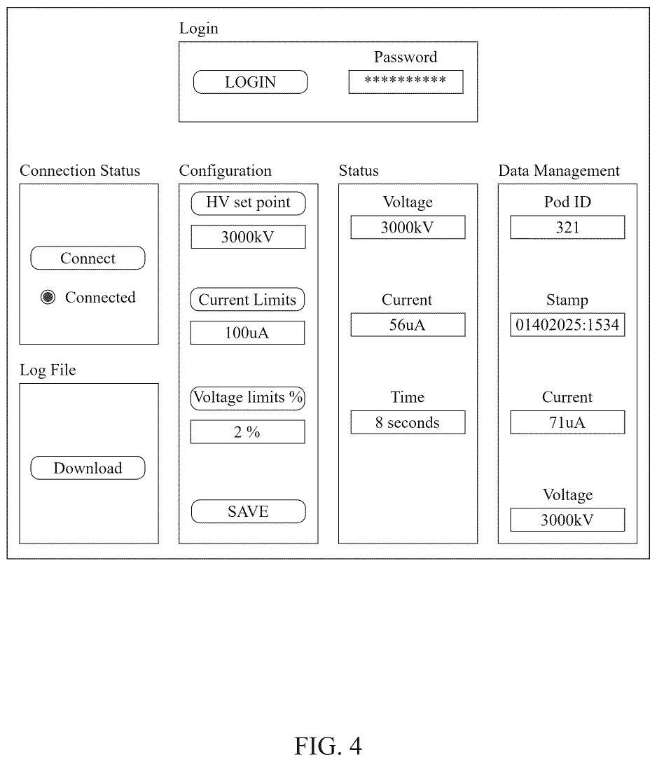

The present invention is a mobile charging device that is used to recharge a mobile electrostatic carrier (MESC) at an alternative location that does not have a typical setup for wired recharging. The present invention does not need to be fixed to a particular location and does not need to act as a large standalone charger. The present invention is preferably used to charge a particle-abatement MESC as described in U.S. Pat. No. 11,772,136 (i.e., U.S. Pat. No. 11,772,136 is incorporated by reference into the current application). Thus, the present invention comprises a device housing 2, a microprocessor 10, a memory module 12, a portable power source 14, a voltage booster circuit 16, a wireless charging coil 18, and at least one trigger sensor 20, which are shown in FIGS. 1 and 2. The device housing 2 is a rigid hollow enclosure that is used to house the electronic and electrical components of the present invention. The device housing 2 is preferably a 2-by-6-by-6-inch box. As can be seen in FIG. 4, the microprocessor 10 is used to manage digital instructions being sent and received amongst the electronic components of the present invention and is used to manage digital information being collected and processed by the electronic components of the present invention. The microprocessor 10 is preferably able to adjust and control logic for battery management, charging parameters, and programing. The memory module 12 is a hardwired component of the present invention that is used to store digital information. The portable power source 14 provides the electrical power that is necessary to recharge an MESC. The portable power source 14 can be, but is not limited to, a lithium polymer battery. The voltage booster circuit 16 is used to convert the electrical power from the portable power source 14 into a high-voltage electrical power. The wireless charging coil 18 is used to inductively charge an MESC with this high-voltage electrical power. The wireless charging coil 18 can be, but is not limited to, a charging pad based on the Qi interface standard for wireless power transfer using inductive charging. The at least one trigger sensor 20 allows the present invention to detect an MESC near the device housing 2 with high precision and is then used to activate the voltage booster circuit 16 and the wireless charging coil 18. The at least one trigger sensor 20 can be, but is not limited to, at least one infrared trigger sensor, at least one contact trigger sensor (e.g., pin contacts), or a combination thereof. The at least one trigger sensor 20 may be programable through the microprocessor 10.

The general configuration of the aforementioned components allows the present invention to efficiently and effectively recharge an MESC without having to take the MESC to a designated charging location. The device housing 2 comprises an outer housing surface 4, an inner housing surface 6, and an MESC-situating housing portion 8. The outer housing surface 4 is the external surface of the device housing 2, while the inner housing surface 6 is the internal surface of the device housing 2. The MESC-situating housing portion 8 is a portion of the device housing 2 that is configured and/or dedicated to situating an MESC as the MESC is recharged by the present invention. In addition, the microprocessor 10, the memory module 12, the portable power source 14, the voltage booster circuit 16, and the wireless charging coil 18 are mounted within the device housing 2, which houses and prevents damage to these components. The wireless charging coil 18 is positioned against the inner housing surface 6 and is positioned adjacent to the MESC-situating housing portion 8 so that the wireless charging coil 18 is able to effectively and efficiently recharge an MESC through the device housing 2. Moreover, the at least one trigger sensor 20 is externally mounted to the device housing 2 and is positioned adjacent to the MESC-situating housing portion 8, which allows the at least one trigger sensor 20 to readily detect the proximity of an MESC to the MESC-situating housing portion 8. Furthermore, the memory module 12, the voltage booster circuit 16, and the at least one trigger sensor 20 are electronically connected to the microprocessor 10, which allows the microprocessor 10 to manage digital instructions and/or digital information amongst these components. The microprocessor 10, the memory module 12, and the at least one trigger sensor 20 are electrically connected to the portable power source 14, which allows the portable power source 14 to provide electrical power to these components during their operation. The wireless charging coil 18 is electrically connected to the portable power source 14 through the voltage booster circuit 16 so that the voltage booster circuit 16 is able to boost the voltage of the electrical power from the portable power source 14, before this electrical power reaches the wireless charging coil 18.

As can be seen in FIGS. 1 and 2, the present invention may further comprise at least one removable-memory slot 22, which is used to interface with an external memory device [e.g., a secure digital (SD) card, a flash drive, etc.] and is used to exchange digital information with the external memory device. The at least one removable-memory slot 22 is integrated into the device housing 2 so that an external memory device can be inserted and securely engaged within the at least one removable-memory slot 22. The at least one removable-memory slot 22 is electronically connected to the microprocessor 10 so that, when an external memory device is inserted into the at least one removable-memory slot 22, the at least one removable-memory slot 22 is able to transfer digital information and/or digital instructions between the microprocessor 10 and the external memory device. The at least one removable-memory slot 22 is electrically connected to the portable power source 14 in order to provide electrical power to the at least one removable-memory slot 22 during its operation.

As can be seen in FIGS. 1 and 2, the present invention may further comprise at least one wireless communication module 24, which is used to wirelessly exchange digital information with another computing device. The at least one wireless communication module 24 is preferably a personal area network (PAN) communication module [e.g., Bluetooth, near field communication (NFC), etc.]. The at least one wireless communication module 24 is mounted within the device housing 2 in order to protect the at least one wireless communication module 24 from any external damage. The at least one wireless communication module 24 is electronically connected to the microprocessor 10 so that, when another computing device is communicably coupled to the microprocessor 10 through the at least one wireless communication module 24 (e.g., “paired” through Bluetooth), the at least one wireless communication module 24 is able to transfer digital information and/or digital instructions between the microprocessor 10 and the other computing device. The at least one wireless communication module 24 is electrically connected to the portable power source 14 in order to provide electrical power to the at least one wireless communication module 24 during its operation.

As can be seen in FIGS. 1 and 2, the present invention may further comprise at least one communication port 26, which is used to exchange digital information with another computing device through a data cable [e.g., a universal serial bus (USB) cable]. The at least one communication port 26 is integrated into the device housing 2 so that an end of a data cable can be inserted and securely engaged within the at least one communication port 26. The at least one communication port 26 is electronically connected to the microprocessor 10 so that, when an end of a data cable is inserted into the at least one communication port 26, and when the other end of the data cable is communicably coupled to another computing device, the at least one communication port 26 is able to transfer digital information and/or digital instructions between the microprocessor 10 and the other computing device through the data cable. The at least one communication port 26 is electrically connected to the portable power source 14 in order to provide electrical power to the at least one communication port 26 during its operation.

As can be seen in FIGS. 1 and 2, the present invention may further comprise a wired charging port 28, which is used to recharge an MESC through a charging cable as an alternative to using the portable power source 14 to recharge the MESC. The wired charging port 28 is integrated into the device housing 2 so that an end of a charging cable can be inserted and securely engaged within the wired charging port 28. The wired charging port 28 is electrically connected to the wireless charging coil 18 through the voltage booster circuit 16 so that the voltage booster circuit 16 is able to again boost the voltage of the electrical power from the wired charging port 28, before this electrical power reaches the wireless charging coil 18.

As can be seen in FIGS. 1 and 2, the present invention may further comprise a source recharging port 30, which is used to recharge the rechargeable battery with an external power source (e.g., a generator, a larger battery, an electrical outlet, etc.) through a charging cable. The source recharging port 30 is integrated into the device housing 2 so that an end of a charging cable can be inserted and securely engaged within the source recharging port 30. The source recharging port 30 is electrically connected to the portable power source 14 so that the rechargeable battery can be readily recharged by an external power source through a charging cable.

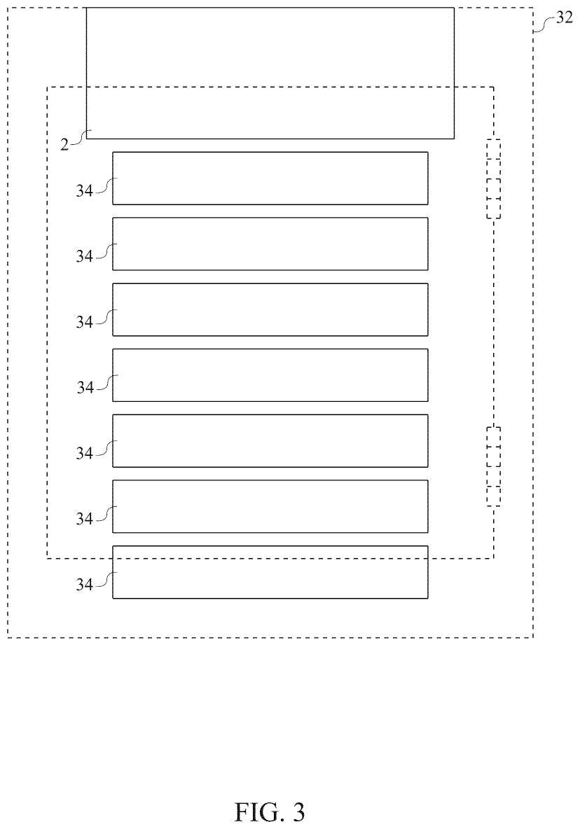

As can be seen in FIG. 3, the present invention may be configured to recharge an MESC within a storage enclosure for the MESC. Thus, the device housing 2 is mounted within a MESC-storing enclosure 32 so that the present invention is able to recharge an MESC 34 while the MESC 34 is idling within the MESC-storing enclosure 32. More specifically, the MESC 34 can be a particle-abatement MESC as described in U.S. Pat. No. 11,772,136. The MESC-storing enclosure 32 can be, but is not limited to, a front opening utility pod (FOUP) or a standard mechanical interface (SMIF) pod, which are two of the more common MESC-storage enclosures. The FOUP is typically used for 300-millimeter (mm) semiconductive wafers, and the SMIF pod is typically used for 200-mm semiconductive wafers. The MESC-storing enclosure 32 can alternatively be any kind of container by retrofitting the present invention into a container, which can be a new-designed box or any existing container.

Although the invention has been explained in relation to its preferred embodiment, it is to be understood that many other possible modifications and variations can be made without departing from the spirit and scope of the invention as hereinafter claimed.

What is claimed is:

1. A mobile charging device for a mobile electrostatic carrier (MESC) comprising:
a device housing;
a microprocessor;
a memory module;
a portable power source;
a voltage booster circuit;
a wireless charging coil;
at least one trigger sensor;
the device housing comprising an outer housing surface, an inner housing surface, and an MESC-situating housing portion;
the microprocessor, the memory module, the portable power source, the voltage booster circuit, the wireless charging coil being mounted within the device housing;
the wireless charging coil being positioned against the inner housing surface;
the wireless charging coil being positioned adjacent to the MESC-situating housing portion;
the at least one trigger sensor being externally mounted to the device housing;
the at least one trigger sensor being positioned adjacent to the MESC-situating housing portion;
the memory module, the voltage booster circuit, and the at least one trigger sensor being electronically connected to the microprocessor;
the microprocessor, the memory module, and the at least one trigger sensor being electrically connected to the portable power source; and
the wireless charging coil being electrically connected to the portable power source through the voltage booster circuit.

2. The mobile charging device for a MESC as claimed in claim 1 comprising:
at least one removable-memory slot;
the at least one removable-memory slot being integrated into the device housing;
the at least one removable-memory slot being electronically connected to the microprocessor; and
the at least one removable-memory slot being electrically connected to the portable power source.

3. The mobile charging device for a MESC as claimed in claim 1 comprising:
at least one wireless communication module;
the at least one wireless communication module being mounted within the device housing;
the at least one wireless communication module being electronically connected to the microprocessor; and
the at least one wireless communication module being electrically connected to the portable power source.

4. The mobile charging device for a MESC as claimed in claim 3, wherein the at least one wireless communication module is a personal area network (PAN) communication module.

5. The mobile charging device for a MESC as claimed in claim 1 comprising:
at least one communication port;
the at least one communication port being integrated into the device housing;
the at least one communication port being electronically connected to the microprocessor; and
the at least one communication port being electrically connected to the portable power source.

6. The mobile charging device for a MESC as claimed in claim 1 comprising:
a wired charging port;
the wired charging port being integrated into the device housing; and
the wired charging port being electrically connected to the wireless charging coil through the voltage booster circuit.

7. The mobile charging device for a MESC as claimed in claim 1 comprising:
a source recharging port;
the source recharging port being integrated into the device housing; and
the source recharging port being electrically connected to the portable power source.

8. The mobile charging device for a MESC as claimed in claim 1, wherein the at least one trigger sensor is at least one infrared trigger sensor.

9. The mobile charging device for a MESC as claimed in claim 1, wherein the at least one trigger sensor is at least one contact trigger sensor.

10. The mobile charging device for a MESC as claimed in claim 1, wherein the at least one trigger sensor is a combination of at least one infrared sensor and at least one contact trigger sensor.

11. The mobile charging device for a MESC as claimed in claim 1 comprising:
an MESC-storing enclosure; and
the device housing being mounted within the MESC-storing enclosure.

12. The mobile charging device for a MESC as claimed in claim 11, wherein the MESC-storing enclosure is a front opening utility pod (FOUP).

13. The mobile charging device for a MESC as claimed in claim 11, wherein the MESC-storing enclosure is a standard mechanical interface (SMIF) pod.
